(19) United States
(12) Patent Application Publication
(10) Pub. No.: US 2008/0191207 A1
(43) Pub. Date: Aug. 14, 2008

(54) THIN FILM TRANSISTOR DEVICE, METHOD OF MANUFACTURING THE SAME, AND DISPLAY APPARATUS

(75) Inventor: Atsunori NISHIURA, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: MITSUBISHI ELECTRIC CORPORATION, Chiyoda-ku (JP)

(21) Appl. No.: 11/965,241

(22) Filed: Dec. 27, 2007

(30) Foreign Application Priority Data
Feb. 8, 2007 (JP) 2007-028807
May 10, 2007 (JP) 2007-125239

(51) Int. Cl. H01L 29/04

(52) U.S. Cl. 257/59; 257/E29.003

(57) ABSTRACT

A thin film transistor device includes a semiconductor layer including a source region, a drain region and a channel region formed above a substrate, a metal film formed in a prescribed area on the semiconductor layer, a gate insulating film formed on the metal film and the semiconductor layer, a gate electrode, an interlayer insulating film, and a line electrode. The metal film is formed on the source region and the drain region of the semiconductor layer, the area being at least a bottom of the contact hole. The thickness of the semiconductor layer in a region on which the metal film is not formed is smaller than the thickness of the semiconductor layer in a region on which the metal film is formed.

### BACKGROUND OF THE INVENTION

1. Field of the Invention

The present invention relates to a thin film transistor (TFT) device that is used for active matrix electro-optic display apparatus and, particularly, liquid crystal display apparatus and organic electroluminescence (EL) display apparatus, a method of manufacturing the TFT device, and the display apparatus.

2. Description of Related Art

Low-profile display apparatus such as liquid crystal display apparatus and EL display apparatus using a TFT have been developed recently. A TFT which uses polysilicon as a material of an active region has an advantage over a TFT which uses amorphous silicon in that it enables formation of a higher-resolution panel, allows integral formation of a driver circuit region and a pixel region, and reduces a cost because it eliminates the need for preparing and mounting a driver circuit chip.

The structure of a TFT is broadly divided into two types: staggered and coplanar. A polysilicon TFT generally has the coplanar structure because high-temperature silicon crystallization can be performed at the beginning of a process. A typical structure and manufacturing process of a coplanar type polysilicon TFT are described hereinafter with reference to FIG. 11.

Referring to FIG. 11, an insulating film 92, which serves as a base film, is formed on a glass substrate 91. On the insulating film 92, a polysilicon film 93 with a thickness of 50 to 100 nm, for example, is formed and patterned. A TFT is thereby formed. If the polysilicon film 93 is located below a gate electrode, the polysilicon film 93 may be used for a conductive film that is different from a channel region. For example, the polysilicon film 93 may be patterned in an area that is different from an active region but is on the extension of the active region for the use as a lower electrode of a storage capacitor. After patterning the polysilicon film 93, a gate insulating film 95, which is made of a silicon oxide film or the like, is formed on the polysilicon film 93. On the gate insulating film 95, a gate electrode 96 and an upper electrode 100 of a storage capacitor are formed, and an interlayer insulating film 97 is further formed thereon. Then, a contact hole 98 with a depth of 500 to 600 nm, for example, is formed in the gate insulating film 95 and the interlayer insulating film 97 so as to reach the polysilicon film 93. Then, a line electrode 99 is formed on the interlayer insulating film 97. The line electrode 99 is connected with the polysilicon film 93 through the contact hole 98. Further, an upper insulating film 101 is formed on the line electrode 99, and an upper contact hole 102 is formed so as to reach the line electrode 99. In order to avoid an opening failure of the upper contact hole 102, the upper contact hole 102 is formed in the position not to overlap with the contact hole 98. Then, a pixel electrode 103 is formed on the upper insulating film 101. The pixel electrode 103 is connected with the line electrode 99 through the upper contact hole 102. Thus, the pixel electrode 103 is connected with the polysilicon film 93 through the pixel electrode 103. An active matrix TFT device is thereby formed.

There are some points to be noted when producing a TFT device that has a polysilicon film placed below a gate electrode as described above. A first point is that, when using a polysilicon film as a lower electrode of a storage capacitor, it is needed to reduce the resistivity of the polysilicon film sufficiently so as to function as a lower electrode. A way to meet this need is to increase the impurity doping amount to the polysilicon film. An increase in the doping amount leads to an increase in the damage to a gate insulating film. It is thereby necessary to increase the doping amount to the polysilicon film while suppressing the damage. For example, Japanese Unexamined Patent Application Publication No. 2001-296550 (Murai) discloses a technique of reducing the resistivity of a region to serve as a lower electrode of a storage capacitor by masking the area other than the storage capacitor when doping an impurity to a polysilicon film that functions as the lower electrode.

A second point is that, when forming a contact hole in an insulating film that is composed of an interlayer insulating film and a gate insulating film so as to reach a polysilicon film located therebelow, it is needed to perform an etching process so as not to penetrate the polysilicon film that serves as the bottom of the contact hole. The penetration causes a failure to connect the bottom of the contact hole and the polysilicon film. In such a case, the electrical connection between a pixel electrode and the polysilicon film through a contact hole can be established only by the polysilicon film that is connected with the side surface of the contact hole, which leads to an increase in connection resistance.

Further, the thickness of the insulating film, which is the total thickness of the interlayer insulating film and the gate insulating film, is about 600 nm. On the other hand, the thickness of the polysilicon film located therebelow is about 50 nm. It is thus extremely difficult to etch the insulating film completely to form contact holes without penetrating the polysilicon film at all only by improving the process uniformity and controllability. Accordingly, such an etching process requires a high etching rate ratio of the insulating film with respect to the polysilicon film. If etching is performed by placing an importance only on the etching rate ratio, it is possible to form a contact hole suitably without penetrating the polysilicon film. However, the etching that places an importance only on the etching rate ratio results in a lower etching rate. Therefore, it takes a long time to make an opening in a very thick insulating film, which leads to a decrease in the productivity of the TFT device. In order to solve the trade-off between the etching rate ratio and the productivity, Japanese Unexamined Patent Application Publication No. 2001-264813 (Kubota), for example, discloses a technique for achieving both selectivity and mass-productivity by performing etching in two or three stages.

Japanese Unexamined Patent Application Publication No. 10-170952 (Murade) discloses a technique of forming a silicon film, a silicide film, a metal film or the like below a polysilicon film to thereby increase an etching process margin so as to overcome both the penetration through a polysilicon film and the insufficient etching.

However, when using a polysilicon film as a lower electrode of a storage capacitor as taught by Murai, it is necessary to dope a high concentration of impurity into the polysilicon film. It takes a long processing time. As a result, the doping process causes a decrease in the mass-productivity of TFT devices. Further, the damage to an insulating film that serves as a capacitor portion of a storage capacitor due to the doping is unavoidable, which leads to degradation of the storage capacitor. Furthermore, when forming a lower electrode using a polysilicon film, it is unable to reduce resistance to a sufficient level only by changing the doping concentration. Therefore, the lower electrode itself has a capacitance component, thus failing to obtain desired storage capacitor characteristics. Besides the storage capacitor characteristics, forming a lower electrode of a storage capacitor with a polysilicon film causes an increase in a resistance component that is formed in series with the storage capacitor.

The technique taught by Kubota, which forms a contact hole by two or three stages of etching, causes a decrease in the mass productivity of semiconductor devices. Further, the technique taught by Murade, which forms another silicon film or the like below a polysilicon film, is less effective in terms of selectivity. In addition, it is unable to completely deal with a fluctuation of the in-plane distribution of a film thickness and an etching rate of an interlayer insulating film. Further, if a contact hole is not formed appropriately, it fails to establish a sufficient conduction between a signal line and a doped region of a polysilicon film. It can also fail to perform suitable signal transmission between a pixel electrode and the doped region of the polysilicon film, which causes display errors.

An approach to overcome the above problems is to form a metal film in the area that is at least located above a doped region of a polysilicon film to form a channel region and that serves as the bottom of a contact hole, for example. In this structure, the metal film may be directly connected with a pixel electrode or the like that is located thereabove through a contact hole. Further, a lower electrode of a storage capacitor may be formed by extending the polysilicon film and the metal film.

The above structure enables reduction of the contact resistance with the pixel electrode or the like in an upper layer that is connected through a contact hole, thus obtaining suitable display characteristics. Further, because the metal film, which has low resistance, is formed on the lower electrode of the storage capacitor, the structure suppresses the degradation of an insulating film upon doping and assures the mass-productivity. It is thereby possible to form a stable capacitor and improve the display characteristics.

However, in the above structure, if the metal film makes a silicide reaction or the like with the polysilicon film, the silicide film cannot be removed completely after the process of removing the metal film under the gate electrode and its vicinity. If the silicide film remains on a channel layer, the silicide film serves as a leakage path between a source and a drain. This results in an increase in off-current to hinder the obtainment of suitable transistor characteristics.

The present invention has been accomplished to solve the above problems and an object of the present invention is thus to provide a thin-film transistor device that establishes a suitable contact of a line with a source region and a drain region of a semiconductor layer, has a stable capacitance of a storage capacitor, reduces a leakage between a source and a drain, improves a withstand voltage of a gate insulating film, and reduces contact resistance, a method of manufacturing the thin-film transistor device, and a display apparatus including the thin-film transistor device.

### SUMMARY OF THE INVENTION

To these ends, according to one aspect of the present invention, there is provided a thin film transistor device that includes a semiconductor layer including a source region, a drain region and a channel region formed above a substrate, a metal film formed in a prescribed area on the semiconductor layer, a gate insulating film formed on the metal film and the semiconductor layer, a gate electrode formed on the gate insulating film, an interlayer insulating film formed on the gate electrode and the gate insulating film, and a line electrode formed on the interlayer insulating film and connected with the metal film through a contact hole. In this thin film transistor device, the metal film is formed in an area on the source region and the drain region of the semiconductor layer, the area being at least a bottom of the contact hole, and a thickness of the semiconductor layer in a region on which the metal film is not formed is smaller than a thickness of the semiconductor layer in a region on which the metal film is formed.

To these ends, according to another aspect of the present invention, there is provided a method of manufacturing a thin film transistor device that includes forming a semiconductor layer including a source region, a drain region and a channel region above a substrate, forming a metal film in a prescribed area on the semiconductor layer, forming a gate insulating film on the metal film and the semiconductor layer, forming a gate electrode on the gate insulating film, forming an interlayer insulating film on the gate electrode and the gate insulating film, and forming a line electrode on the interlayer insulating film to be connected with the metal film through a contact hole. In this method, the metal film is formed in an area on the source region and the drain region of the semiconductor layer, the area being at least a bottom of the contact hole, and a thickness of the semiconductor layer in a region on which the metal film is not formed is smaller than a thickness of the semiconductor layer in a region on which the metal film is formed.

The thin-film transistor device according to the present invention establishes a suitable contact of a line with a source region and a drain region of a semiconductor layer, has a stable capacitance of a storage capacitor, reduces a leakage between a source and a drain, improves a withstand voltage of a gate insulating film, and reduces contact resistance.

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

FIG. 1 is a schematic plan view showing the structure of a TFT array substrate according to an embodiment of the present invention;

FIGS. 2A to 2C are sectional views showing a manufacturing process of a TFT device according to the first embodiment of the present invention;

FIGS. 3A and 3B are sectional views showing a manufacturing process of a TFT device according to the first embodiment of the present invention;

FIG. 4 is a sectional view showing a part of the TFT device shown in FIG. 3;

FIGS. 5A to 5C are sectional views showing a process of forming a metal film on a polysilicon film;

FIG. 6 is a view showing a gate withstand voltage of a gate insulating film;

FIG. 7 is a sectional view showing a TFT device according to a second embodiment of the present invention;

FIG. 8 is a sectional view showing a TFT device according to a third embodiment of the present invention;

FIG. 9 is a sectional view showing a TFT device according to a related art as a comparison with the third embodiment;

FIG. 10 is a sectional view showing a TFT device according to a fourth embodiment of the present invention; and

FIG. 11 is a sectional view showing a TFT device according to a related art.

### DETAILED DESCRIPTION OF REFERRED EMBODIMENTS

### First Embodiment

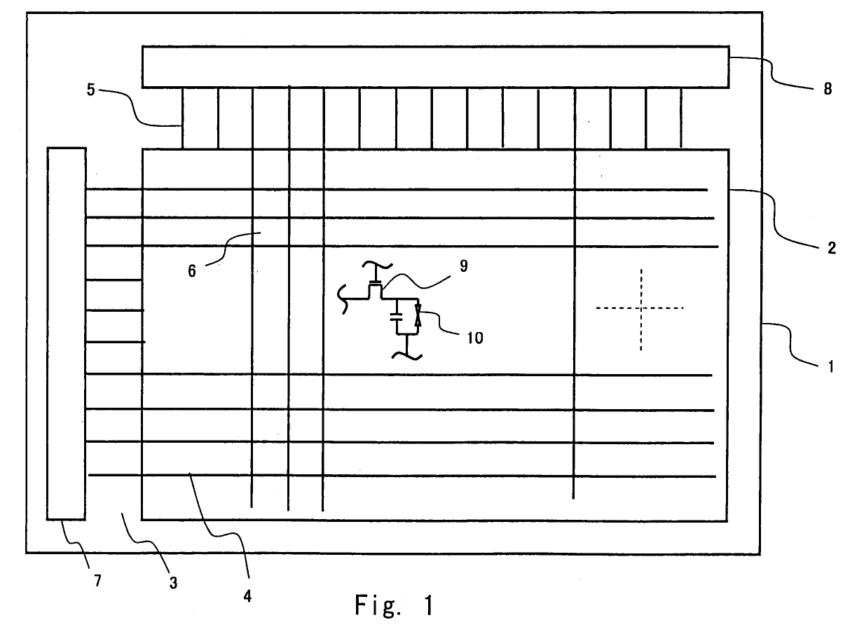

Exemplary embodiments of the present invention are described hereinafter with reference to the drawings. A thin film transistor device according to an embodiment of the present invention constitutes a TFT array substrate 1. FIG. 1 is a schematic plan view showing the structure of the TFT array substrate 1. The TFT array substrate 1 includes a display area 2 and a frame area 3 surrounding the display area 2. In the display area 2, a plurality of gate signal lines 4 and a plurality of source signal lines 5 are formed. The plurality of gate signal lines 4 are arranged in parallel with each other. Likewise, the plurality of source signal lines 5 are arranged in parallel with each other. The gate signal lines 4 and the source signal lines 5 are orthogonal to each other. Each region that is surrounded by the gate signal lines 4 and the source signal lines 5 is a pixel 6. Thus, the pixels 6 are arranged in a matrix on the TFT array substrate 1.

In the frame area 3 of the TFT array substrate 1, a gate signal driver circuit 7 and a source signal driver circuit 8 are formed. The gate signal lines 4 and the source signal lines 5 run from the display area 2 to the frame area 3. The gate signal lines 4 are connected with the gate signal driver circuit 7 at an end of the TFT array substrate 1. External lines, which are not shown, are formed in close proximity to the gate signal driver circuit 7 and connected with the gate signal driver circuit 7. The source signal lines 5 are connected with the source signal driver circuit 8 at another end of the TFT array substrate 1. External lines, which are not shown, are also formed in close proximity to the source signal driver circuit 8 and connected with the source signal driver circuit 8.

In each pixel 6, at least one TFT 9 and a storage capacitor 10 are formed. The TFT 9 is placed in close proximity to the intersection of the gate signal line 4 and the source signal line 5. The storage capacitor 10 is connected in series with the TFT 9.

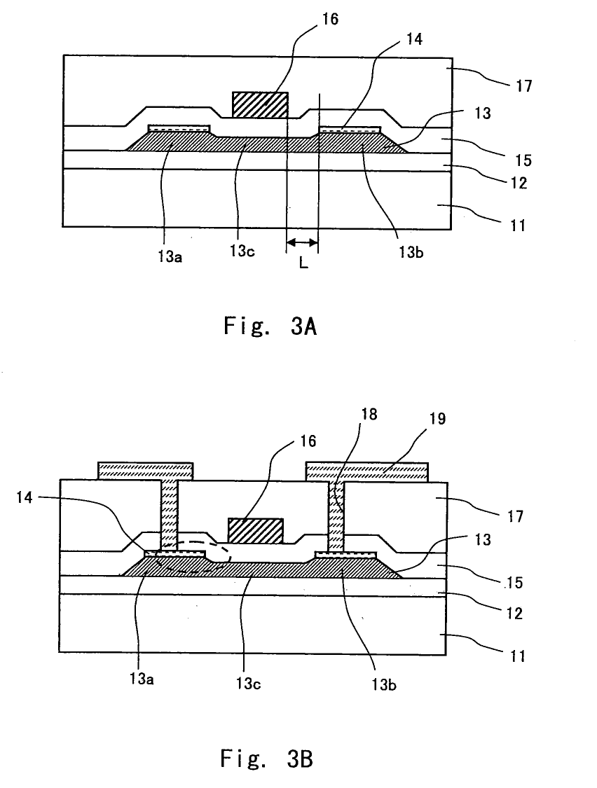

The TFT array substrate 1 having such a structure is described hereinafter in further detail. According to this embodiment, the present invention may be applied to a liquid crystal panel substrate that is a thin film transistor device which constitutes a liquid crystal display apparatus, for example. FIG. 3B is a sectional view of a thin film transistor device (which is referred to hereinafter as a TFT device) that constitutes the TFT array substrate 1 according to this embodiment. As shown in FIG. 3B, a protective insulating film 12 is formed on a glass substrate 11. A polysilicon film 13 that serves as a semiconductor layer is formed on the protective insulating film 12. In the polysilicon film 13, a source region 13a and a drain region 13b are formed on both sides of a channel region 13c. A metal film 14 is formed on the polysilicon film 13. A gate insulating film 15 is formed on the metal film 14. A gate electrode 16 is formed opposite to the channel region 13c with the gate insulating film 15 interposed therebetween. An interlayer insulating film 17, which is made of SiO₂ or the like, is formed thereon. A contact hole 18 is formed in the interlayer insulating film 17 and the gate insulating film 15 so as to reach the metal film 14. A line electrode 19 is formed on the interlayer insulating film 17. The line electrode 19 is connected with the metal film 14 that is formed on the source region 13a and the drain region 13b through the contact hole 18.

In the TFT device shown in FIG. 3B, the metal film 14 is formed in an area on the source region 13a and the drain region 13b, the area being at least a bottom of the contact hole 18. This avoids the penetration through the polysilicon film 13 in the etching process to form the contact hole 18. The reason is described later. Further, the line electrode 19 can be connected at low resistance with the source region 13a and the drain region 13b of the polysilicon film 13 through the metal film 14. This improves the display characteristics of a display apparatus that includes the TFT device. As described later, a silicide film or the like that is formed on the channel region 13c is removed by etching. This prevents the deterioration of transistor characteristics due to a leakage path between a source and a drain or the like. Further, as described later, the metal film 14 that is formed on the polysilicon film 13 is pattered by wet etching, for example. The surface roughness of the channel region 13c, which is the region from which the metal film 14 is removed, is smaller than the surface roughness of the source region 13a and the drain region 13b, which are the regions of the polysilicon film 13 on which the metal film 14 is formed. This improves the withstand voltage of the gate insulating film 15. The detail is described later.

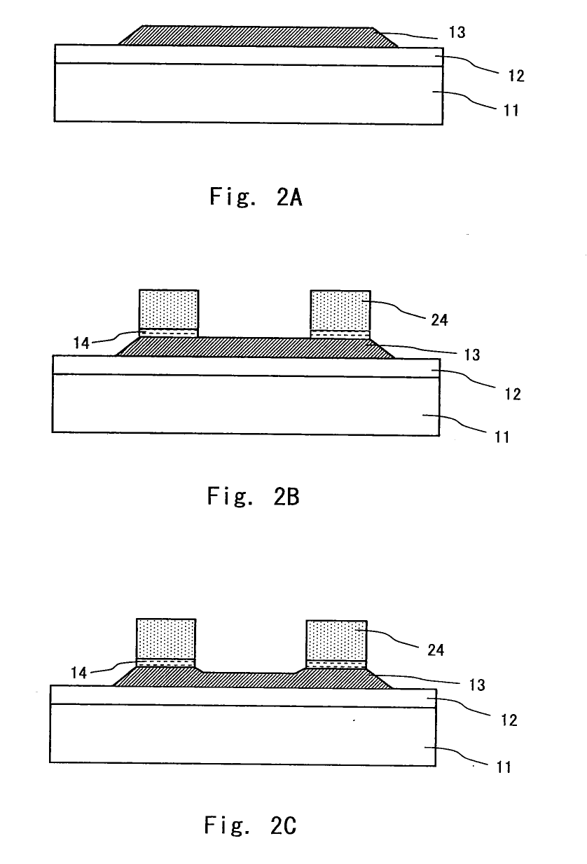

A method of manufacturing the TFT device shown in FIG. 3B is described hereinafter with reference to FIGS. 2A to 2C, 3A, and 3B. Referring first to FIG. 2A, the protective insulating film 12, which is made of an insulating film such as a silicon oxide film or a silicon nitride film, is formed on the surface of the substrate 11, which is made of a quartz substrate or a glass substrate, by a CVD process. The polysilicon film 13 having a thickness of 50 to 200 nm, for example, is formed on the protective insulating film 12. The polysilicon film 13 is then patterned by etching, thereby forming an island-shaped polysilicon film 13. In the polysilicon film 13, the source region 13a and the drain region 13b are formed with the channel region 13c placed therebetween in a subsequent process (not shown).

Referring next to FIG. 2B, the metal film 14 is formed on the polysilicon film 13 by sputtering or the like. Then, the metal film 14 is patterned by photolithography or wet etching using a mixed solution of phosphoric acid and nitric acid or the like. The metal film 14 to be left after patterning is in the area that is located on the source region 13a and the drain region 13b, the area being at least the bottom of the contact hole 18, which is described later. If the metal film 14 is too thick, doping of an impurity into the polysilicon film 13 that is placed below the metal film 14 is difficult. Thus, the thickness of the metal film 14 is preferably about 20 nm or smaller. It is further preferred to perform heat treatment at a temperature of about 350° C. to 500° C. on the metal film 14 in a subsequent process in order to improve a TFT threshold and mobility. To facilitate the heat treatment, the metal film 14 is preferably made of a high melting point metal such as Ti (titanium), Ta (tantalum), W (tungsten) and Mo (molybdenum), or a conductive metallic compound such as TiN, TaN, WN, MoN, ZrN, VN, NbN, TiB₂, ZrB₂, HfB₂, VB₂, NbB₂, or TaB₂. Then, a resist 24 is formed on the metal film 14.

Referring then to FIG. 2C, a part of the polysilicon film 13 other than the source region 13a and the drain region 13b on which the metal film 14 is formed is etched about 2 to 20 nm by dry etching using mixed gas of CF₄ and CHF₃, for example. The metal film 14 and the polysilicon film 13 are thereby formed, and a silicide film or the like that is not removed by the patterning of the metal film 14 is removed from the area on the channel region 13c of the polysilicon film 13. If the silicide film remains on the surface of the channel region 13c, it can be a leakage path between a source and a drain. In this case, off-current increases to deteriorate the transistor characteristics. Further, by dry-etching the surface of the polysilicon film 13, the surface roughness of the polysilicon film 13 is reduced to thereby improve the withstand voltage of the gate insulating film, which is described later. Furthermore, by removing the silicide film or the like that is formed above the channel region 13c, the thickness of the polysilicon film 13 in the channel region 13c is reduced. This can reduce a TFT threshold voltage Vth.

Referring further to FIG. 3A, the gate insulating film 15 with a thickness of 70 to 150 nm, for example, is formed on the protective insulating film 12, the polysilicon film 13 and the metal film 14. The gate insulating film 15 may be made of a silicon oxide layer, for example. After that, a metal film to become a gate electrode of a TFT is formed on the gate insulating film 15 by sputtering or the like. The thickness of the metal film is preferably 100 to 150 nm. Then, the metal film is etched and patterned to thereby form the gate electrode 16. Using the gate electrode 16 as a mask, regions to become the source region 13a and the drain region 13b are formed in the polysilicon film 13, which is an active layer of a TFT, by self-alignment by ion implantation of an impurity such as phosphorus. The impurity is not implanted into a region below the gate electrode 16. The region where the impurity is not implanted serves as the channel region 13c.

As shown in FIG. 3A, a distance L between the end of the gate electrode 16 on the side of the drain region 13b and the end of the metal film 14 formed on the drain region 13b on the side of the channel region 13c is preferably L≧1 μm in order to prevent TFT leakage. Then, the interlayer insulating film 17, which is made of a silicon oxide film or the like, is formed oh the gate electrode 16 and the gate insulating film 15 by the CVD process, for example. The thickness of the interlayer insulating film 17 is preferably 300 to 700 nm.

Referring then to FIG. 3B, the contact hole 18 is formed in the interlayer insulating film 17 and the gate insulating film 15 so as to reach the metal film 14 that is formed on the polysilicon film 13 by anisotropic dry etching, for example. The dry etching may be reactive ion etching, chemical dry etching, or plasma etching or the like with the use of CF₄ and SF₆ as etching gas. At this time, an etching rate may be modified by changing a mixing ratio of etching gas.

In the chemical dry etching or the plasma etching, an etching rate ratio between the polysilicon film 13 and a silicon oxide film is generally about 10 or above. Thus, the etching rate of the polysilicon film 13 is higher than the etching rate of the silicon oxide film as the gate insulating film 15. Accordingly, in the chemical dry etching or the plasma etching, the etching does not stop at the surface of the polysilicon film 13 but penetrates the polysilicon film 13 in some cases. On the other hand, in the reactive ion etching, it is possible to set the etching rate of the polysilicon film 13 to be lower than the etching rate of the silicon oxide film by inverting the etching rate ratio. However, in order to form a plurality of contact holes 18 in the substrate, it is necessary to perform over-etching in consideration of the non-uniform thickness of the interlayer insulating film 17. In addition, the thickness of the polysilicon film 13 is smaller than the thickness of the interlayer insulating film 17. It is therefore difficult to stop the etching at the surface of the polysilicon film 13. Further, if the etching rate of the polysilicon film 13 is set to be lower than the etching rate of the silicon oxide film by inverting the etching rate ratio, the overall etching rate decreases, which deteriorates the mass-productivity of TFT devices and causes residue to be left on the etching surface. This raises a need for after-treatment to remove the residue.

In view of the foregoing, this embodiment forms the metal film 14 on the source region 13a and the drain region 13b of the polysilicon film 13 so that the metal film 14 corresponds at least to the bottom of the contact hole 18. The metal film 14 is thereby formed at the bottom of the contact hole 18. It is generally easy to set an etching rate ratio between a metal film and a silicon oxide film to be substantially less than 1. Thus, by forming the metal film 14 on the polysilicon film 13, it is possible to prevent the contact hole 18 from penetrating the polysilicon film 13 upon etching, thereby establishing a suitable connection of the line electrode with the source region 13a and the drain region 13b as described later.

After that, a low-resistance conductive film such as aluminum is formed all over the substrate of the TFT device by sputtering or the like and then patterned, thereby forming the line electrode 19 on the interlayer insulating film 17. The line electrode 19 is connected to the source region 13a or the drain region 13b through the contact hole 18 and the metal film 14.

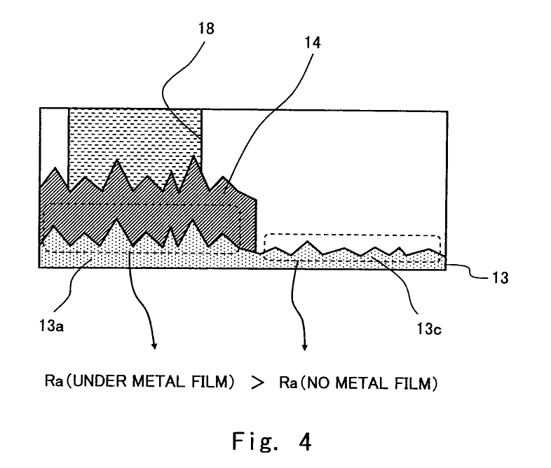

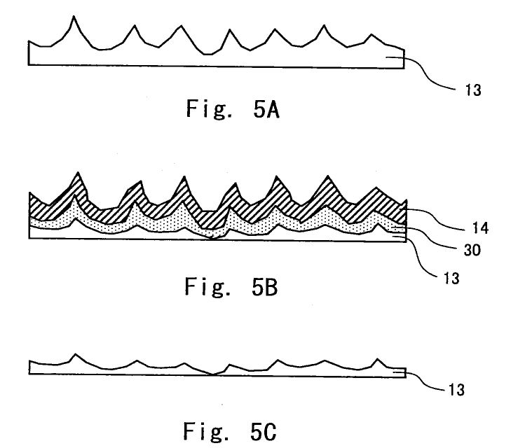

FIG. 4 shows an enlarged view of the part within the dotted circle of the thin film transistor device shown in FIG. 3B. As shown in FIG. 4, the surface roughness of the polysilicon film 13, which is a semiconductor layer, differs between the source region 13a where the metal film 14 is formed on the polysilicon film 13 and the channel region 13c where the metal film 14 is not formed thereon. The surface of the polysilicon film 13 in the channel region 13c where the metal film 14 is not formed has a smaller roughness than the surface of the polysilicon film 13 in the source region 13a where the metal film 14 is formed. A difference in the surface roughness of the polysilicon film 13 is described hereinbelow with reference to FIGS. 5A to 5C.

FIGS. 5A to 5C are sectional views showing the process of forming the metal film 14 on the polysilicon film 13 and then removing the metal film 14. Referring first to FIG. 5A, the surface of the polysilicon film 13 is rough. Referring next to FIG. 5B, the metal film 14 is formed on the polysilicon film 13. At this time, a silicide film 30 with a thickness of about 1 to 3 mm is formed between the polysilicon film 13 and the metal film 14. Referring then to FIG. 5C, the silicide film 30 and the metal film 14 are removed by wet etching, for example. Because the silicide film 30 and the metal film 14 that are formed on the polysilicon film 13 are removed by etching, the surface roughness of the polysilicon film 13 is reduced. Accordingly, the surface of a part of the polysilicon film 13 from which the metal film 14 is removed as shown in FIG. 5C is less rough than the surface of the polysilicon film 13 shown in FIG. 5A. The surface roughness Ra, which is specified by JISB0601, of the polysilicon film 13 where the metal film 14 and the silicide film 30 are removed is substantially ½ and below of the surface roughness Ra of the polysilicon film 13 where the metal film 14 is formed. Because the surface roughness of the polysilicon film 13 is reduced, a gate dielectric withstand voltage of the gate insulating film 15, which is formed on the polysilicon film 13, can be improved. If the silicide film 30 and the metal film 14 on the channel region 13c are removed by dry etching, the surface roughness of the polysilicon film 13 from which the silicide film 30 and the metal film 14 are removed can be further reduced. This enables further improvement of a gate dielectric withstand voltage of the gate insulating film 15. The surface roughness of the polysilicon film 13 may be formed larger in the source region 13a and the drain region 13b. This increases the contact area of the source region 13a and the drain region 13b with the line electrode 19 through the metal film 14, thereby reducing contact resistance.

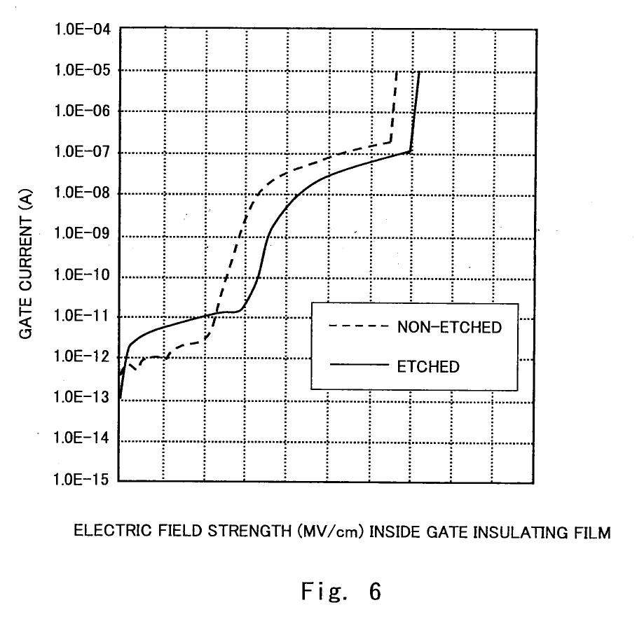

FIG. 6 shows a gate dielectric withstand voltage in the cases of etching and not etching the channel region 13c of the polysilicon film 13. In FIG. 6, the horizontal axis of the graph indicates an electric field strength (MV/cm) inside the gate insulating film, and the vertical axis indicates a gate current (A). As shown in FIG. 6, the etched polysilicon film 13 has a higher gate dielectric withstand voltage than the non-etched polysilicon film 13.

As described above, this embodiment forms the metal film 14 in the area that is located on the source region 13a and the drain region 13b of the polysilicon film 13, the area being at least the bottom of the contact hole 18. Further, the embodiment sets the etching rate ratio between the metal film and the silicon oxide film to substantially less than 1 and performs etching for forming the contact hole 18. It is thereby possible to prevent the contact hole 18 from penetrating the polysilicon film 13 during the etching. It is also possible to suppress an increase in contact resistance between the source region 13a or the drain region 13b and the line electrode 19. Furthermore, the embodiment etches the surface of the channel region 13c on which the metal film 14 is not formed, so that the thickness of the channel region 13c is smaller than the thickness of the source region 13a and the drain region 13b on which the metal film 14 is formed. The silicide film or the like is thereby removed, and it is thus possible to prevent the degradation of the transistor characteristics due to a leakage path between a source and a drain or the like. In addition, the embodiment forms the metal film 14 on the polysilicon film 13 and removes the metal film 14 in the channel region 13c, thus reducing the surface roughness of the polysilicon film 13 in the channel region 13c. It is thereby possible to improve the gate dielectric withstand voltage of the gate insulating film 15.

### Second Embodiment

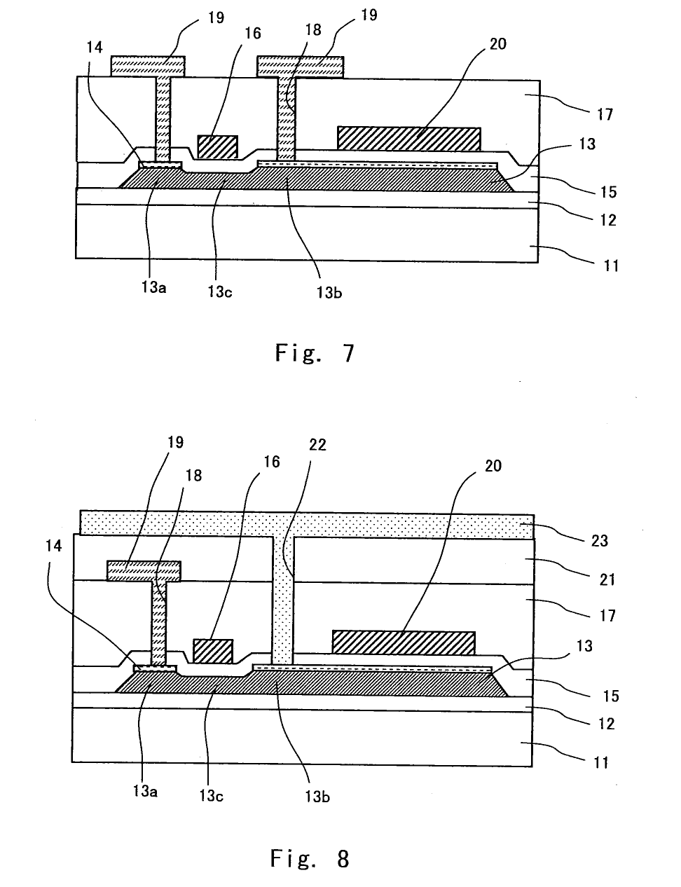

A display apparatus according to a second embodiment of the present invention is described hereinafter with reference to FIG. 7. FIG. 7 is a sectional view of the TFT device according to the second embodiment. In the TFT device of the second embodiment shown in FIG. 7, the same elements as in the first embodiment shown in FIGS. 2A to 3B are denoted by the same reference numerals and not described in detail herein.

The TFT device shown in FIG. 7 is different from the TFT device of the first embodiment shown in FIGS. 2A to 3B in that it includes an upper electrode 20 of a storage capacitor which is formed in the same layer as the gate electrode 16 and that a lamination of the metal film 14 and the polysilicon film 13 is used as a lower electrode that is opposite to the upper electrode 20 of the storage capacitor with the gate insulating film 15 interposed therebetween.

A method of manufacturing the TFT device according to this embodiment is described hereinafter in detail. The detailed manufacturing method of the TFT device that is common to that of the first embodiment is not repeated herein. When patterning the polysilicon film 13 into an island shape and when forming the metal film 14, the polysilicon film 13 and the metal film 14 are formed so as to extend to an area where a lower electrode of a storage capacitor is formed. Then, the gate insulating film 15 is formed on the metal film 14. The gate insulating film 15 that is formed above the polysilicon film 13 and the metal film 14, which function as the lower electrode of the storage capacitor, serves as a dielectric film of the storage capacitor. Thus, the dielectric film of the storage capacitor and the gate insulating film 15 are made of the same material. Then, a metal film that is formed on the gate insulating film 15 is patterned to thereby form the gate electrode 16 and the upper electrode 20 of the storage capacitor. Thus, the gate electrode 16 and the upper electrode 20 of the storage capacitor are made of the same material. The upper electrode 20 of the storage capacitor is placed in the position opposite to the metal film 14 that is formed on the polysilicon film 13 with the gate insulating film 15 that serves as the dielectric film of the storage capacitor interposed therebetween.

If the lower electrode of the storage capacitor is composed of the polysilicon film 13 only as in a related art, it is necessary to dope a high dose impurity into the polysilicon film 13 before forming the upper electrode 20 of the storage capacitor in order to reduce the resistivity of the lower electrode. This embodiment eliminates the need for such a doping process because the metal film 14 is formed on the polysilicon film 13 and thereby the resistance of the resistivity of the lower electrode is lowered. After forming the gate electrode 16 and the upper electrode 20 of the storage capacitor, the interlayer insulating film 17, the contact hole 18 and the line electrode 19 are formed sequentially in the same manner as in the first embodiment.

The dielectric film that is formed between the upper electrode 20 and the lower electrode of the storage capacitor may be the gate insulating film 15 as described above. In this case, the manufacturing process of the TFT device does not increase because the gate insulating film 15 is used as the dielectric film of the storage capacitor. Although the gate insulating film 15 is used as the dielectric film of the storage capacitor in this embodiment, the present invention is not limited thereto, and another film may be formed separately. For example, an insulating film with a high dielectric constant, such as a silicon nitride film, may be formed separately. This enables an increase in the capacitance of the storage capacitor.

According to this embodiment having such a structure, the polysilicon film 13 and the metal film 14 are formed to extend to the area where the lower electrode of the storage capacitor is formed. Specifically, the metal film 14 is formed in the area that is located on the source region 13a and drain region 13b, the area being at least the bottom of the contact hole 18. The metal film 14 and the silicide film 30 that are formed on the channel region 13c are removed by etching. Further, the metal film 14 is formed on the polysilicon film 13 that serves as the lower electrode of the storage capacitor. Because the silicide film or the like that is formed above the channel region 13c is removed, the thickness of the channel region 13c on which the metal film 14 is not formed is smaller than the thickness of the source region 13a and the drain region 13b on which the metal film 14 is formed. Furthermore, the gate insulating film 15 is formed so as to extend to the storage capacitor, so that the gate insulating film 15 serves as the dielectric film of the storage capacitor. On the gate insulating film 15, the upper electrode 20 of the storage capacitor is formed in the same layer as the gate electrode 16.

This embodiment forms the metal film 14 in the area on the source region 13a and the drain region 13b of the polysilicon layer, the area being at least the bottom of the contact hole 18, and it is thus possible to prevent the contact hole 18 from penetrating the polysilicon film 13 during etching. The embodiment removes the silicide film or the like, thus preventing the deterioration of the transistor characteristics due to a leakage path between a source and a drain or the like. Further, because the embodiment uses a lamination of the metal film 14 and the polysilicon film 13 as the lower electrode of the storage capacitor, there is no need to perform a doping process for reducing the resistance of the lower electrode, which significantly reduces a process time to manufacture the TFT device. In this structure, the resistance of the lower electrode of the storage capacitor is lower compared with the case where the lower electrode is composed only of the polysilicon film 13, thereby reducing the resistance component that is formed in series with the storage capacitor. It is thereby possible to stabilize the capacitance of the storage capacitor. Furthermore, the embodiment removes the silicide film and the metal film 14 that are formed on the channel region 13c of the polysilicon film 13, so that the surface roughness of the channel region 13c in the polysilicon film 13 is reduced. It is thereby possible to improve the gate dielectric withstand voltage of the gate insulating film 15.

### Third Embodiment

A TFT device according to a third embodiment of the present invention is described hereinafter with reference to FIGS. 3A and 8. The TFT device shown in FIG. 8 is different from the TFT device of the first embodiment shown in FIGS. 2A to 3B in that it includes an upper insulating film 21 that is formed on the interlayer insulating film 17, a pixel electrode 23 that is formed on the upper insulating film 21, and an upper contact hole 22 to connect the pixel electrode 23 with the metal film 14.

Specifically, in the TFT device shown in FIG. 3A, the interlayer insulating film 17 and the gate insulating film 15 are etched so as to reach the metal film 14 that is formed on the source region 13a, thereby forming the contact hole 18. Then, the line electrode 19 is formed on the interlayer insulating film 17, so that it is connected with the source region 13a or the drain region 13b through the metal film 14. As the upper insulating film 21, a silicon oxide film or a silicon nitride film, for example, is formed by the CVD process or the like. Alternatively, a resin film or the like may be coated. A laminated film or those may be used instead. After that, the upper insulating film 21, the interlayer insulating film 17 and the gate insulating film 15 are etched in such a way that the metal film 14 that is formed on the drain region 13b is exposed, thereby forming the upper contact hole 22. Then, the pixel electrode 23 is formed on the upper insulating film 21, so that the pixel electrode 23 is connected with the metal film 14. The pixel electrode 23 may be formed by depositing a transparent conductive material such as ITO or a metal material such as Al by sputtering and then patterning the material, for example.

The insulating film that is etched when forming the upper contact hole 22 is the upper insulating film 21, the interlayer insulating film 17, and the gate insulating film 15. In the first embodiment, the insulating film that is etched when forming the contact hole 18 above the drain region 13b is the interlayer insulating film 17 and the gate insulating film 15. Thus, the thickness of the insulating film to be etched is larger to form the upper contact hole 22 in this embodiment. If the insulating film to be etched is thick, it is needed to perform the etching for a long time in order to enlarge the opening at the bottom of the contact hole. This increases the possibility that the contact hole that is formed by the etching penetrates the polysilicon film 13. However, because the metal film 14 is formed on the polysilicon film 13, it is possible to remove the insulating film without penetrating the polysilicon film 13 during the etching process to form the upper contact hole 22. Because the pixel electrode 23 and the drain region 13b are connected through the metal film 14, the connection can be established with low resistance, thus improving the display characteristics of the display apparatus.

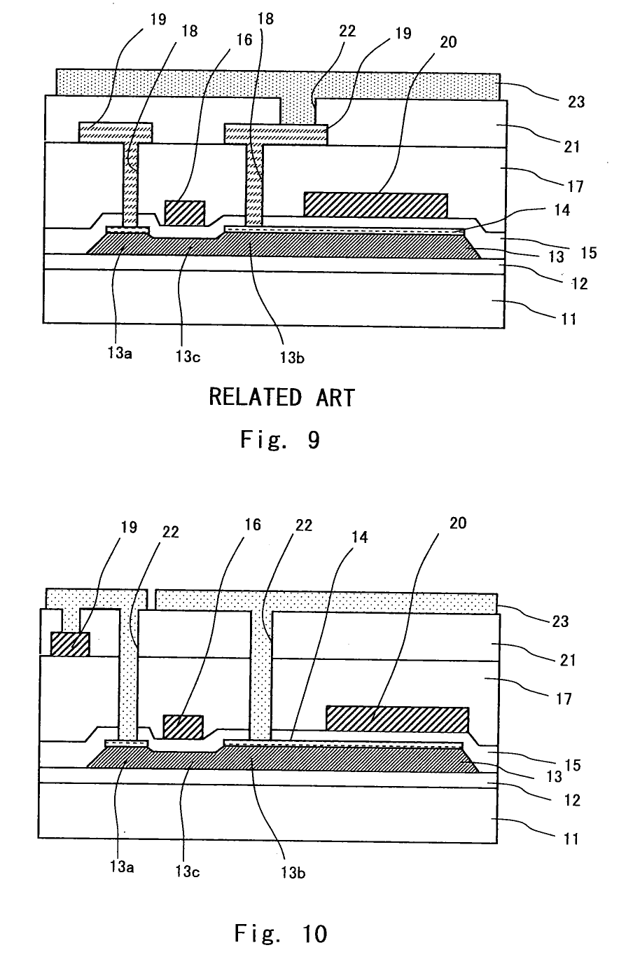

FIG. 9 shows the TFT device that has the upper contact hole 22 according to a related art. As shown in FIG. 9, in the related art, the pixel electrode 23 is connected with the line electrode 19 through the upper contact hole 22. Further, the line electrode 19 is connected with the metal film 14 through the contact hole 18. On the other hand, in the TFT device of this embodiment, a conductive layer that is placed between the pixel electrode 23 and the drain region 13b is reduced from two kinds (i.e. the line electrode 19 and the metal film 14) to one kind (i.e. the metal film 14). This embodiment thus reduces the conductive layer that is placed between the pixel electrode 23 and the drain region 13b from two kinds to one kind. This reduces the contact resistance that is generated between conductive layers of different materials, thus reducing the contact resistance of the entire TFT device to thereby improve the display characteristics of the display apparatus.

According to this embodiment having such a structure, the metal film 14 is formed in the area that is located on the source region 13a, the area being at least the bottom of the contact hole 18. Further, the metal film 14 is formed in the area that is located on the drain region 13b, the area being at least the bottom of the upper contact hole 22. The metal film 14 and the silicide film 30 that are formed above the channel region 13c are removed by etching or the like. Because the silicide film or the like that is formed above the channel region 13c is removed, the thickness of the channel region 13c on which the metal film 14 is not formed is smaller than the thickness of the source region 13a and the drain region 13b on which the metal film 14 is formed. Furthermore, the upper insulating film 21 is formed on the line electrode 19. Then, the upper insulating film 21, the interlayer insulating film 17 and the gate insulating film 15 are etched to thereby form the upper contact hole 22. Finally, the pixel electrode 23 is formed on the upper insulating film 21.

This embodiment forms the metal film 14 in the area on the source region 13a and the drain region 13b, the area being at least the bottom of the contact hole 18 and the upper contact hole 22, and it is thus possible to prevent the contact hole 18 and the upper contact hole 22 from penetrating the polysilicon film 13 during the etching. The embodiment removes the silicide film or the like that is formed above the channel region 13c, thus preventing the deterioration of the transistor characteristics due to a leakage path between a source and a drain or the like. Further, because the conductive film that is placed between the pixel electrode 23 and the drain region 13b of the polysilicon film 13 is only the metal film 14 in this embodiment, the contact resistance of the entire TFT device decreases. It is thereby possible to improve the display characteristics of the display apparatus. Further, the embodiment removes the metal film 14 and the silicide film 30 that are formed above the channel region 13c of the polysilicon film 13. This reduces the surface roughness of the channel region 13c of the polysilicon film 13, and it is thereby possible to improve the gate dielectric withstand voltage of the gate insulating film 15.

### Fourth Embodiment

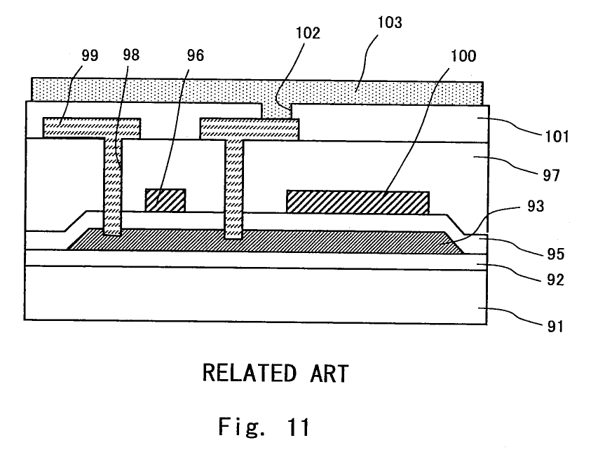

A TFT device according to a fourth embodiment of the present invention is described hereinafter with reference to FIG. 3A and FIG. 10. The TFT device shown in FIG. 10 is different from the TFT device of the first embodiment shown in FIGS. 2A to 3B in that the line electrode 19 is formed on the interlayer insulating film 17 and that the line electrode 19 is connected with the metal film 14 not directly but through the pixel electrode 23 that is formed on the upper insulating film 21.

Specifically, after forming the interlayer insulating film 17 in the TFT device as shown in FIG. 3A, the line electrode 19 is formed on the interlayer insulating film 17 in an area that is not above the source region 13a and the drain region 13b. Then, the upper insulating film 21 is formed on the line electrode 19. After that, the upper contact hole 22 is formed so as to reach the metal film 14 that is formed on the source region 13a and the drain region 13b. The pixel electrode 23 is then formed on the upper insulating film 21, so that the line electrode 19 is connected with the metal film 14 through the pixel electrode 23. This embodiment forms the upper contact holes 22 respectively on the source region 13a and the drain region 13b in one process and connects the pixel electrode 23 that is formed on the upper insulating film 21 with the metal film 14. It is thereby possible to reduce a process time for manufacturing the TFT device. It is also possible to reduce the number of masks required for forming contact holes.

According to this embodiment having such a structure, the metal film 14 is formed in the area that is located on the source region 13a and the drain region 13b, the area being at least the bottom of the upper contact hole 22. The metal film 14 and the silicide film 30 that are formed above the channel region 13c are removed by etching or the like. Because the silicide film or the like that is formed above the channel region 13c is removed, the thickness of the channel region 13c on which the metal film 14 is not formed is smaller than the thickness of the source region 13a and the drain region 13b on which the metal film 14 is formed. Furthermore, the line electrode 19 is formed on the interlayer insulating film 17, and the pixel electrode 23 is formed on the upper insulating film 21 that is formed on the line electrode 19. The line electrode 19 is connected with the metal film 14 through the pixel electrode 23. Because this embodiment forms the metal film 14 in the area on the source region 13a and the drain region 13b, the area being at least the bottom of the upper contact hole 22, it is possible to prevent the upper contact hole 22 from penetrating the polysilicon film 13 during etching. Because the embodiment removes the silicide film or the like that is formed above the channel region 13c, it prevents the deterioration of the transistor characteristics due to a leakage path or the like between a source and a drain. Further, the embodiment enables formation of the upper contact holes 22 respectively on the source region 13a and the drain region 13b in one process, so that it is possible to further reduce a time for manufacturing the TFT device. Furthermore, the embodiment removes the metal film 14 and the silicide film 30 that are formed above the channel region 13c of the polysilicon film 13, so that it is possible to reduce the surface roughness of the channel region 13c of the polysilicon film 13. This improves the gate dielectric withstand voltage of the gate insulating film 15.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A thin film transistor device comprising:
a semiconductor layer including a source region, a drain region and a channel region formed above a substrate;
a metal film formed in a prescribed area on the semiconductor layer;
a gate insulating film formed on the metal film and the semiconductor layer;
a gate electrode formed on the gate insulating film;
an interlayer insulating film formed on the gate electrode and the gate insulating film; and
a line electrode formed on the interlayer insulating film and connected with the metal film through a contact hole, wherein
the metal film is formed in an area on the source region and the drain region of the semiconductor layer, the area being at least a bottom of the contact hole, and
a thickness of the semiconductor layer in a region on which the metal film is not formed is smaller than a thickness of the semiconductor layer in a region on which the metal film is formed.

2. A thin film transistor device comprising:
a semiconductor layer including a source region, a drain region and a channel region formed above a substrate;
a metal film formed in a prescribed area on the semiconductor layer;
a gate insulating film formed on the metal film and the semiconductor layer;
a gate electrode formed on the gate insulating film;
an interlayer insulating film formed on the gate electrode and the gate insulating film;
a line electrode formed on the interlayer insulating film and connected with the metal film formed on the source region through a contact hole;
an upper insulating film formed on the line electrode; and
a pixel electrode formed on the upper insulating film and connected with the metal film formed on the drain region through an upper contact hole, wherein
the metal film is formed in an area on the source region and the drain region of the semiconductor layer, the area being at least a bottom of the contact hole and the upper contact hole, and
a thickness of the semiconductor layer in a region on which the metal film is not formed is smaller than a thickness of the semiconductor layer in a region on which the metal film is formed.

3. A thin film transistor device comprising:
a semiconductor layer including a source region, a drain region and a channel region formed above a substrate;
a metal film formed in a prescribed area on the semiconductor layer;
a gate insulating film formed on the metal film and the semiconductor layer;
a gate electrode formed on the gate insulating film;
an interlayer insulating film formed on the gate electrode and the gate insulating film;
a line electrode formed on the interlayer insulating film;
an upper insulating film formed on the interlayer insulating film and the line electrode; and
a pixel electrode formed on the upper insulating film to connect the line electrode with the metal film through an upper contact hole, wherein
the metal film is formed in an area on the source region and the drain region of the semiconductor layer, the area being at least a bottom of the upper contact hole,
a thickness of the semiconductor layer in a region on which the metal film is not formed is smaller than a thickness of the semiconductor layer in a region on which the metal film is formed, and
the line electrode is connected with the metal film through the pixel electrode.

4. A thin film transistor device comprising:
a semiconductor layer including a source region, a drain region and a channel region formed above a substrate;
a metal film formed in a prescribed area on the semiconductor layer;
a gate insulating film formed on the metal film and the semiconductor layer;
a gate electrode formed on the gate insulating film;
an interlayer insulating film formed on the gate electrode and the gate insulating film; and
a line electrode formed on the interlayer insulating film and connected with the metal film through a contact hole, wherein
the metal film is formed in an area on the source region and the drain region of the semiconductor layer, the area being at least a bottom of the contact hole,
a thickness of the semiconductor layer in a region on which the metal film is not formed is smaller than a thickness of the semiconductor layer in a region on which the metal film is formed, and
a surface roughness of the semiconductor layer in the region on which the metal film is not formed is smaller than a surface roughness of the semiconductor layer in the region on which the metal film is formed.

5. A thin film transistor device comprising:
a semiconductor layer including a source region, a drain region and a channel region formed above a substrate;
a metal film formed in a prescribed area on the semiconductor layer;
a gate insulating film formed on the metal film and the semiconductor layer;
a gate electrode formed on the gate insulating film;
an interlayer insulating film formed on the gate electrode and the gate insulating film; and
a line electrode formed on the interlayer insulating film and connected with the metal film through a contact hole, wherein
the metal film is formed in an area on the source region and the drain region of the semiconductor layer, the area being at least a bottom of the contact hole,
a thickness of the semiconductor layer in a region on which the metal film is not formed is smaller than a thickness of the semiconductor layer in a region on which the metal film is formed, and
a surface roughness Ra specified by JISB0601 of the semiconductor layer in the region on which the metal film is not formed is ½ and below of a surface roughness of the semiconductor layer in the region on which the metal film is formed.

6. The thin film transistor device according to claim 1, further comprising:
a semiconductor layer formed above the substrate to extend to an area to serve as a storage capacitor;
a metal film formed on the semiconductor layer;
a gate insulating film formed on the metal film to serve as a dielectric film of the storage capacitor; and
an upper electrode of the storage capacitor formed on the gate insulating film.

7. The thin film transistor device according to claim 6, wherein
the gate electrode and the upper electrode of the storage capacitor are made of the same material.

8. The thin film transistor device according to claim 6, wherein
the gate insulating film and the gate insulating film to serve as a dielectric film of the storage capacitor are made of the same material.

9. The thin film transistor device according to claim 1, wherein
the metal film is made of a high melting point metal or a conductive metallic compound.

10. The thin film transistor device according to claim 9, wherein
the high melting point metal is at least one selected from Ti, Ta, W and Mo, and the conductive metallic compound is at least one selected from TiN, TaN, WN, MoN, ZrN, VN, NbN, TiB₂, ZrB₂, HfB₂, VB₂, NbB₂ and TaB₂.
